(19) United States
(12) Patent Application Publication
(10) Pub. No.: US 2026/0311963 A1
(43) Pub. Date: Oct. 8, 2026

(54) ION IMPLANTER AND ION IMPLANTATION METHOD

(71) Applicants: Shanghai Advanced Silicon Technology Co., LTD, Shanghai (CN); Chongqing Advanced Silicon Technology Co., LTD, Chongqing (CN)

(72) Inventors: Meng Chen, Shanghai (CN); Fei Ye, Shanghai (CN); Chenbin Zhang, Shanghai (CN)

(73) Assignees: Shanghai Advanced Silicon Technology Co., LTD, Shanghai (CN); Chongqing Advanced Silicon Technology Co., LTD, Chongqing (CN)

(21) Appl. No.: 19/472,095

(22) PCT Filed: Mar. 21, 2024
(86) PCT No.: PCT/CN2024/082951

§ 371 Date: Oct. 2, 2025

(30) Foreign Application Priority Data
Nov. 30, 2023 (CN) 202311630169.0

(51) Int. Cl. H01J 37/30; H01J 37/317; H10P 72/00

(52) U.S. Cl. CPC H01J 37/3007; H01J 37/3171; H10P 72/0402; H01J 2237/1503; H01J 2237/20214; H01J 2237/303; H01J 2237/31701

(57) ABSTRACT

Disclosed are an ion implanter and an ion implantation method. The ion implanter includes: a target disk, comprising a plurality of wafer placement sites arranged along a circumference, wherein the target disk rotates at a speed of less than 200 revolutions per minute; and an ion source, facing the target disk, and configured to perform scanning ion implantation on a surface of a wafer positioned in each of the wafer placement sites along a radial direction of the target disk, wherein a scanning frequency is greater than 500 Hz. According to the present disclosure, the target disk 20 no longer needs to move up and down in a direction perpendicular to the direction of ion implantation to perform mechanical scanning, which greatly simplifies the motion mechanism of the disk and the difficulty of fabrication. The scanning frequency may be set to a high frequency greater than 500 Hz.

### TECHNICAL FIELD

The present disclosure relates to the technical field of semiconductor devices, and in particular, relates to an ion implanter and an ion implantation method.

### BACKGROUND

In the technical route of fabricating silicon-on-insulator (SOI) substrates via hydrogen ion implantation and layer exfoliation, the hydrogen ion implanter is the most critical piece of equipment. In the related art, hydrogen ion implanters typically employ an implantation method that combines electrical scanning and mechanical scanning. FIG. 1A is a schematic structural diagram of an ion implanter in the related art. The ion implanter includes a target disk 10 and an ion source 11. The target disk 10 includes a plurality of wafer placement sites 101 arranged along a circumference. The ion source 11 is disposed facing the target disk to accelerate and implant ions into surfaces of wafers. FIG. 1B is a schematic diagram of a scan path at an enlarged, single scanning position. The scan path 12 is a path traced by the implanted ions on the target disk 10. To ensure that the entire wafer area is implanted, the target disk 10 is required to move vertically (up and down) in a direction perpendicular to the direction of ion implantation, and the scanning frequency is limited to only from 20 to 30 Hz. Furthermore, to achieve implantation uniformity, the target disk 10 is required to rotate at a high speed of over 1000 revolutions per minute (rpm). Evidently, the disadvantages of the aforementioned design include a complex structure and low implantation efficiency.

### SUMMARY

Embodiments of the present disclosure are intended to provide an ion implanter and an ion implantation method, which features simple structure and high implantation efficiency.

In one aspect, the embodiments of the present disclosure provide an ion implanter. The ion implanter includes: a target disk, comprising a plurality of wafer placement sites arranged along a circumference, wherein the target disk rotates at a speed of less than 200 revolutions per minute; and an ion source, facing the target disk, and configured to perform scanning ion implantation on a surface of a wafer positioned in each of the wafer placement sites along a radial direction of the target disk, wherein a scanning frequency is greater than 500 Hz.

In some embodiments, the scanning frequency is from 500 Hz to 1000 Hz.

In some embodiments, a rotational speed of the target disk is from 30 to 200 revolutions per minute.

In some embodiments, an energy of the implanted ions is from 100 keV to 200 keV.

In some embodiments, for the scanning ion implantation along the radial direction of the target disk, a scanning speed of the ion source within a single period is inversely proportional to a distance from a center of rotation of the target disk.

In another aspect, the embodiments of the present disclosure provide an ion implantation method. The method includes: placing wafers to be implanted on a target disk, the target disk comprising a plurality of wafer placement sites arranged along a circumference, wherein the target disk is rotated at a speed of less than 200 revolutions per minute; and performing scanning ion implantation on the wafers on the target disk along a radial direction of the target disk at a scanning frequency greater than 500 Hz.

In some embodiments, the scanning frequency is from 500 Hz to 1000 Hz.

In some embodiments, a rotational speed of the target disk is from 30 to 200 revolutions per minute.

In some embodiments, an energy of the implanted ions is from 100 keV to 200 keV.

In some embodiments, for the scanning ion implantation along the radial direction of the target disk, a scanning speed of the ion source within a single period is inversely proportional to a distance from a center of rotation of the target disk.

According to the present disclosure, the target disk 20 no longer needs to move up and down in a direction perpendicular to the direction of ion implantation to perform mechanical scanning, which greatly simplifies the motion mechanism of the disk and the difficulty of fabrication. The scanning frequency may be set to a high frequency greater than 500 Hz. With the target disk rotating at a speed of less than 200 revolutions per minute, the implantation uniformity still satisfies process requirements. In addition, the dosage loss due to overscan is avoided, and the implantation efficiency of the ion implanter is more than doubled.

### BRIEF DESCRIPTION OF THE DRAWINGS

FIG. 1A is a schematic structural diagram of an ion implanter in the related art;

FIG. 1B is a schematic diagram of a scan path at an enlarged, single scanning position in the structure as illustrated in FIG. 1;

FIG. 2 is a schematic structural diagram of an ion implanter according to a specific embodiment of the present disclosure;

FIG. 3 is a schematic diagram of a scan path at an enlarged, single scanning position in the structure as illustrated in FIG. 2; and

FIG. 4 is a schematic diagram of steps of an ion implantation method according to a specific embodiment of the present disclosure.

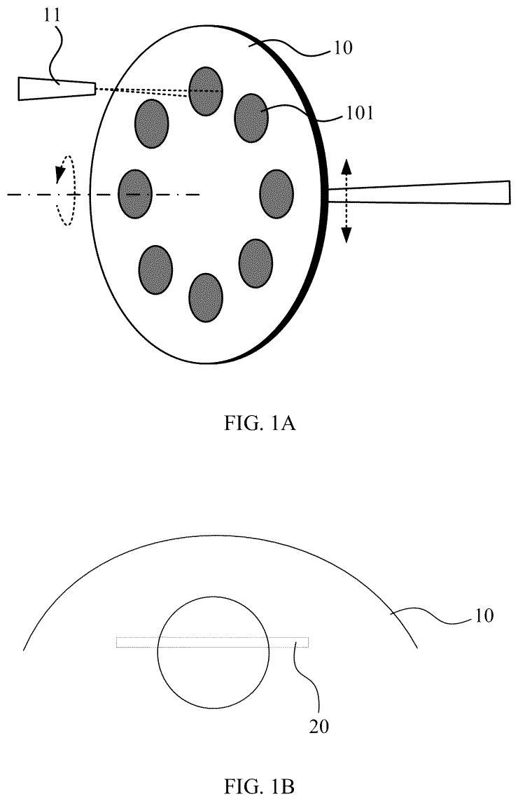

### DETAILED DESCRIPTION

Hereinafter, specific embodiments of an ion implanter and an ion implantation method according to the present disclosure are described in detail with reference to the accompanying drawings.

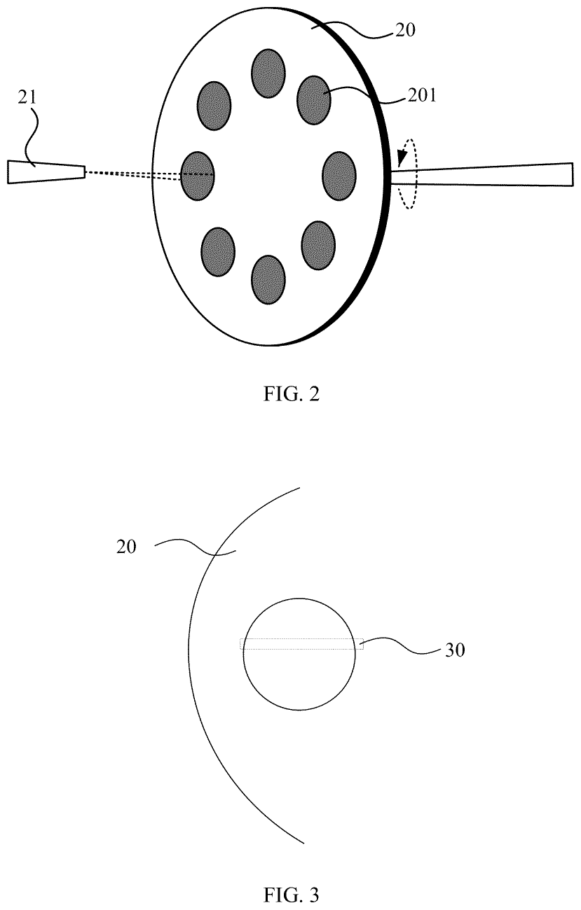

FIG. 2 is a schematic structural diagram of an ion implanter according to a specific embodiment of the present disclosure. The implanter includes: a target disk 20 and an ion source 21. The target disk 20 includes a plurality of wafer placement sites 201 arranged along a circumference, wherein the target disk rotates at a speed of less than 200 revolutions per minute. The ion source 21 is disposed facing the target disk 20 to accelerate and implant ions into surfaces of wafers. In this specific embodiment, the ion source 21 performs scanning ion implantation in the surface of a wafer positioned in each of the wafer placement sites 201 along a radial direction of the target disk 20, wherein a scanning frequency is greater than 500 Hz. More preferably, the scanning frequency is set to from 500 Hz to 1000 Hz. A rotational speed of the target disk is set to from 30 to 200 revolutions per minute, and an energy of the implanted ions is from 100 keV to 200 keV.

FIG. 3 is a schematic diagram of a scan path at an enlarged, single scanning position in the specific embodiment. The scan path 30 is a path traced by the implanted ions on the target disk 20. The direction of an arrow indicates a scanning direction, which is along the radial direction of the target disk 20 from the outside inwards. In other specific embodiments, the scanning may also be performed from the inside outwards, or reciprocative scanning. The scan path 30 is slightly larger than a diameter of the wafer to ensure that ions are implanted into an entire area of the wafer. Evidently, with the scan path, the target disk 20 no longer needs to move up and down in a direction perpendicular to the direction of ion implantation to perform mechanical scanning, which greatly simplifies the motion mechanism of the disk and the difficulty of fabrication. For an ion implanter that eliminates mechanical scanning, because the relative vertical position between the target disk 20 and the ion source 21 is fixed, the scanning frequency may be set to a high frequency greater than 500 Hz. With the target disk rotating at a speed of less than 200 revolutions per minute, the implantation uniformity still satisfies process requirements. Furthermore, with mechanical scanning, the instability of the mechanical mechanism dictates that a large amount of overscan is required to ensure implantation uniformity. The ion implanter utilizes only the electrical scanning technique, thereby greatly avoiding dose loss from overscan. In comparison, under the same beam current injection conditions, more ions may be implanted into the wafer rather than on the periphery of the wafer. In practice, the implantation efficiency of the ion implanter is more than doubled.

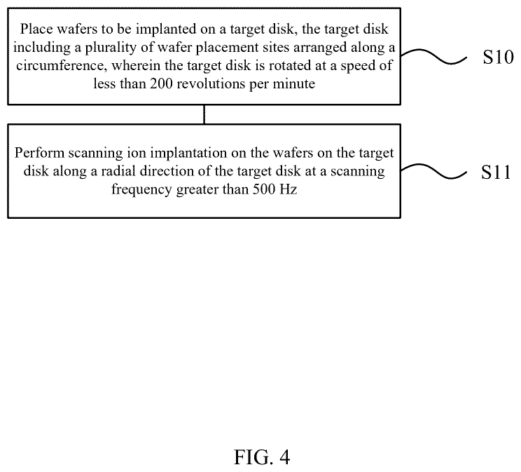

FIG. 4 is a schematic flowchart of steps of an ion implantation method according to a specific embodiment of the present disclosure. The method is performed using the ion implanter as described above. The method includes: S10, placing wafers to be implanted on a target disk, the target disk comprising a plurality of wafer placement sites arranged along a circumference, wherein the target disk is rotated at a speed of less than 200 revolutions per minute; and S11, performing scanning ion implantation on the wafers on the target disk along a radial direction of the target disk at a scanning frequency greater than 500 Hz.

For an explanation and limitations of the above steps, reference may be made to the corresponding content in the previous specific embodiment.

Described above are exemplary embodiments of the present disclosure. It should be noted that persons of ordinary skill in the art may derive other improvements or polishments without departing from the principles of the present disclosure. Such improvements and polishments shall be deemed as falling within the protection scope of the present disclosure.

1. An ion implanter, comprising:
a target disk, comprising a plurality of wafer placement sites arranged along a circumference, wherein the target disk rotates at a speed of less than 200 revolutions per minute; and
an ion source, facing the target disk, and configured to perform scanning ion implantation on a surface of a wafer positioned in each of the wafer placement sites along a radial direction of the target disk, wherein a scanning frequency is greater than 500 Hz.

2. The ion implanter according to claim 1, wherein the scanning frequency is from 500 Hz to 1000 Hz.

3. The ion implanter according to claim 1, wherein a rotational speed of the target disk is from 30 to 200 revolutions per minute.

4. The ion implanter according to claim 1, wherein an energy of the implanted ions is from 100 keV to 200 keV.

5. The ion implanter according to claim 1, wherein for the scanning ion implantation along the radial direction of the target disk, a scanning speed of the ion source within a single period is inversely proportional to a distance from a center of rotation of the target disk.

6. An ion implantation method, comprising:
placing wafers to be implanted on a target disk, the target disk comprising a plurality of wafer placement sites arranged along a circumference, wherein the target disk is rotated at a speed of less than 200 revolutions per minute; and
performing scanning ion implantation on the wafers on the target disk along a radial direction of the target disk at a scanning frequency greater than 500 Hz.

7. The ion implantation method according to claim 6, wherein the scanning frequency is from 500 Hz to 1000 Hz.

8. The ion implantation method according to claim 6, wherein a rotational speed of the target disk is from 30 to 200 revolutions per minute.

9. The ion implantation method according to claim 6, wherein an energy of the implanted ions is from 100 keV to 200 keV.

10. The ion implantation method according to claim 6, wherein for the scanning ion implantation along the radial direction of the target disk, a scanning speed of the ion source within a single period is inversely proportional to a distance from a center of rotation of the target disk.
